(19) United States
(12) Patent Application Publication
(10) Pub. No.: US 2008/0251019 A1
(43) Pub. Date: Oct. 16, 2008

(54) SYSTEM AND METHOD FOR TRANSFERRING A SUBSTRATE INTO AND OUT OF A REDUCED VOLUME CHAMBER ACCOMMODATING MULTIPLE SUBSTRATES

(76) Inventors: SRIRAM KRISHNASWAMI, Saratoga, CA (US); Hung T. Nguyen, Fremont, CA (US); George Tzeng, Redwood City, CA (US); Matthias Brunner, Kirchheim (DE)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/871,510

(22) Filed: Oct. 12, 2007

Related U.S. Application Data
(60) Provisional application No. 60/911,496, filed on Apr. 12, 2007.

(51) Int. Cl. B05C 11/00; H01L 21/02

(52) U.S. Cl. 118/729; 414/225.01

(57) ABSTRACT

The present invention comprises a system and method for transferring a substrate into and out of a chamber configured to accommodate multiple substrates. In one embodiment, the system comprises a chamber housing that includes a first substrate support tray and a second substrate support tray independently movable along a vertical axis, and a substrate conveyor movable into and out of the chamber housing. The first substrate support tray and the second substrate support tray are movable to a position where a portion of the second substrate support tray is received in the first substrate support tray.

### CROSS-REFERENCE TO RELATED APPLICATIONS

This application claims benefit of U.S. provisional patent application Ser. No. 60/911,496 (Attorney Docket No. 11673L), filed Apr. 12, 2007, which is herein incorporated by reference.

### BACKGROUND OF THE INVENTION

1. Field of the Invention

Embodiments described herein generally relate to a method and system for transferring a substrate into and out a chamber configured to accommodate multiple substrates.

2. Description of the Related Art

Semiconductor processes for large area substrates in the production of flat panel displays include processes such as deposition, etching, and testing, which are conventionally conducted in a vacuum chamber. Large area substrates are typically transferred into and out of the vacuum chamber by an atmospheric/vacuum interface, sometimes referred to as a load lock chamber, which provides a staged vacuum between atmospheric pressure and a pressure within the vacuum chamber. In some systems, the load lock chamber may be configured as a transfer chamber coupled between an atmospheric queuing system and the vacuum chamber for atmospheric to vacuum exchange. Likewise, processed substrates may be transferred out of the vacuum chamber to atmospheric conditions through the transfer chamber.

To enable higher throughput, these transfer chambers are conventionally sized for accommodating two substrates at one time. However, due to the size of the large area substrates (2200 mm×2400 mm and larger), the dimensions of at least one of these substrates requires a large internal volume that must be pumped down and vented at each transfer cycle. When the internal volume is sized for more than one substrate, the internal volume of the transfer chamber is even larger. The large internal volume creates a challenge in pump down time as a plurality of large roughing pumps are needed to accomplish the pump down in a short period of time.

Therefore, there is a need for a system that can accommodate multiple large area substrates having a minimized chamber volume, so that the chamber can be negatively pressurized with the same number of pumps to minimize pump down and vent time, which minimizes costs and enhances throughput.

### SUMMARY OF THE INVENTION

The present invention generally comprises embodiments of a system and method for transferring a substrate into and out of a chamber configured to accommodate a plurality of substrates.

In one embodiment, a vacuum chamber sized to receive at least two large area substrates is described. The vacuum chamber includes a housing having an interior volume, and a first support tray and a second support tray disposed in the interior volume. Each of the first and second support trays comprise a plurality of substantially parallel and spaced apart support members defining a first horizontal plane that are coupled to a base portion disposed in a second horizontal plane that is different than the first horizontal plane, wherein the first support tray has a greater dimension than the second support tray.

In another embodiment, a substrate transfer system is described. The substrate transfer system includes a chamber housing having at least one access port, wherein the chamber housing includes a first substrate support tray and a second substrate support tray parallel to the first substrate support tray, wherein the first and second substrate support trays are independently movable along a vertical axis. The chamber housing also includes a substrate conveyor movable into and out of the chamber housing to transfer a substrate between the substrate conveyor and either of the first and second substrate support tray, wherein the first substrate support tray and the second substrate support tray are movable relative to each other to a position where a portion of the second substrate support tray is nested in the first substrate support tray to reduce an internal volume of the housing.

In another embodiment, a method of transferring a large area substrate is described. The method includes placing the substrate on a substrate conveyor, moving the substrate conveyor into a load lock chamber having a substrate support structure, wherein the substrate support structure includes at least a first substrate support tray and a second substrate support tray independently movable along a vertical axis. The method also includes and operating the substrate support structure to transfer the substrate from the substrate conveyor to either of the first and second substrate support trays, wherein operating the substrate support structure includes moving the first substrate support tray relative to the second substrate support tray to a position where a portion of the second substrate support tray is nested in the first substrate support tray to reduce an interior volume of the load lock chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side view of a load lock chamber according to one embodiment;

FIG. 2 is an isometric view of a substrate support suitable for use within the load lock chamber of FIG. 1 according to an embodiment;

FIGS. 3-6 are schematic views showing the implementation of a first substrate transfer cycle according to one embodiment;

FIGS. 7-10 are schematic views showing the implementation of a second substrate transfer cycle according to another embodiment;

FIGS. 11-13 are schematic views showing the implementation of a third substrate transfer cycle according to another embodiment;

FIGS. 14-17 are schematic views showing the implementation of a fourth substrate transfer cycle according to another embodiment;

FIG. 18 is a side cutaway view of a portion of the chamber shown in FIG. 1 according to another embodiment;

FIG. 19 is an isometric view of another embodiment of a load lock chamber; and

FIG. 20 is a side cutaway view of a portion of the chamber shown in FIG. 19.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to a system and method for transferring substrates that are applicable for various chambers configured to accommodate multiple substrates. Although the embodiments are exemplarily described for use in transfer devices, such as load lock chambers or other chambers configured to provide an atmospheric/vacuum interface, some embodiments may be applicable for other chambers configured for two or more substrates. Examples include, without limitations, processing chambers, testing chambers, deposition chambers, and thermal treatment chambers. Substrates, as described herein, include large area substrates made of glass, a polymer material, or other material suitable for forming electronic devices thereon, that are configured for flat panel display production, solar cell array production, and other electronic devices that may be formed on large area substrates. Examples include thin film transistors (TFT's), organic light emitting diodes (OLED's), and p in junctions or other devices used in the manufacture of solar arrays and/or photovoltaic cells.

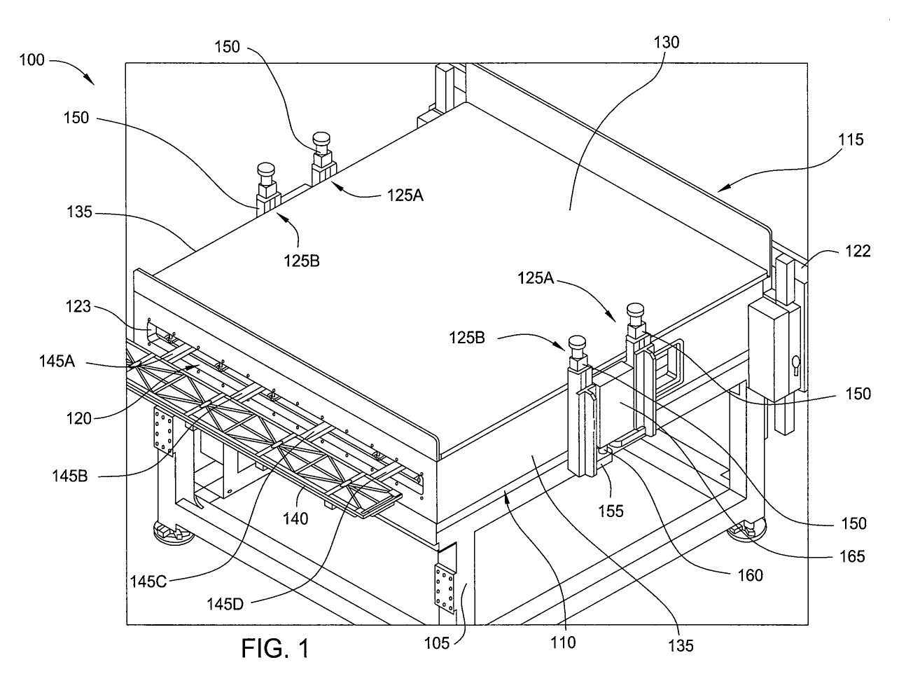

FIG. 1 is an isometric view of a load lock chamber 100, which includes a sealable housing 110 that is disposed on a support frame 105. The housing 110 comprises sidewalls 135, a bottom (not shown in this view), and a lid 130. The housing 110 has a first end 115 and a second end 120, each of which includes an access port 123 that is selectively opened and closed by a valve 122. The first end 115 may be an atmospheric interface, which may be an interface for an atmospheric robot or other transfer device disposed in a clean room. The second end 120 may be a processing interface adapted to be coupled to and in selective communication with a vacuum chamber (not shown) configured for processing a large area substrate, such as a deposition chamber, an etch chamber, a testing chamber, and the like. The vacuum chamber coupled to second end 120 may include a conveyor 140 that may be a robot or other transfer mechanism couple to a substrate support within the vacuum chamber. The conveyor 140 may include blades or another supporting portion, which in this embodiment is configured as a plurality of spaced apart fingers 145A-145D having an upper surface adapted to support and transfer a large area substrate. In one embodiment, the conveyor 140 is configured as an end effector adapted to extend and retract into and out of the vacuum chamber to transfer substrates to and from the load lock chamber 100. An example of a load lock chamber 100 and a vacuum chamber coupled thereto is described in U.S. Patent Publication No. 2006/0273815, filed Dec. 8, 2005 and published on Dec. 7, 2006, which is incorporated by reference herein.

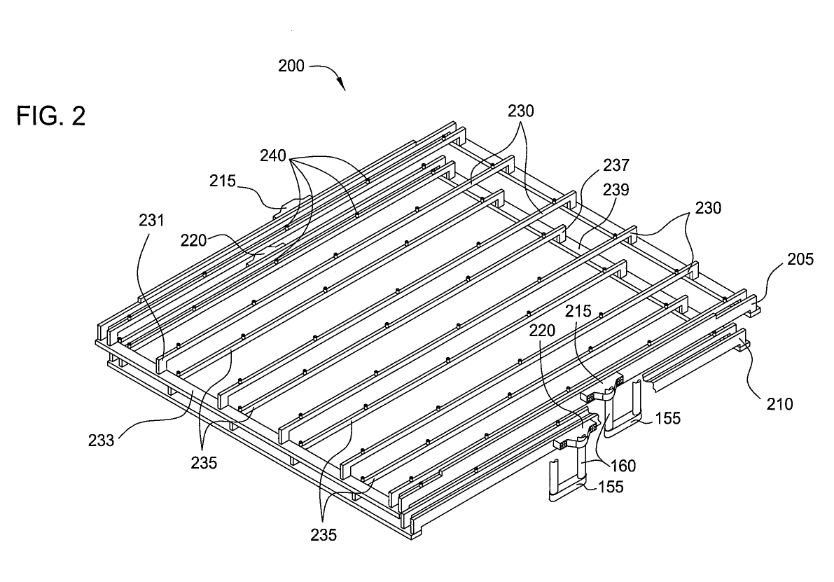

The housing 110 also includes a first pair of actuator assemblies 125A mounted on two opposing sidewalls 135 of the housing 110, and a second pair of actuator assemblies 125B also mounted on the two opposing sidewalls 135 of the housing 110. The actuator assemblies 125A and 125B are coupled to a substrate support structure 200 (FIG. 2) disposed in the interior volume of the housing 110. In one embodiment, each of the actuator assemblies 125A, 125B are coupled to the substrate support structure by a support arm 160 (only 1 is shown in FIG. 1 and may be seen more clearly in FIG. 2) through the sidewalls 135 of the housing 110. The support arms 160 coupling the actuator assemblies 125A, 125B to a respective support tray 205, 210 (FIG. 2) of the substrate support structure may be coupled through the sidewalls 135 by a vacuum tight seal.

The actuator assemblies 125A, 125B are configured as vertical actuators although other movement paradigms may also be provided. Each of the actuator assemblies 125A, 125B includes a drive mechanism or motor 150, which may be electrical, hydraulic, pneumatic, or other mechanical drive adapted to provide at least vertical movement. Each motor 150 by is coupled to a respective support arm 160 by a base 155. The actuator assemblies 125A, 125B are effectively sealed from the interior volume of the load lock chamber 100 to allow vacuum application to the interior volume. In one embodiment, each support arm 160 may include a seal (not shown) that is configured to allow at least vertical movement to the support arm 160, such as a bellows, a flexible boot, or other sealing device configured to seal the interior volume of the load lock chamber 100 from ambient atmosphere. A cover 165 may also be used to house each support arm 160 and may also function as a seal. A more detailed description of one application of an actuator sealing arrangement may be found in the description of FIGS. 10 and 11 of U.S. Patent Publication No. 2006/0273815, previously incorporated by reference.

FIG. 2 is an isometric view of one embodiment of the substrate support structure 200 adapted to be disposed in the interior volume of the load lock chamber 100 of FIG. 1. The substrate support structure 200 includes an upper support tray 205 and a lower support tray 210 that are arranged vertically in a substantially parallel orientation. The upper support tray 205 and lower support tray 210 comprises support points 215, 220, respectively, that are adapted to be coupled to respective actuator assemblies 125A, 125B by support arms 160. The upper support tray 205 and lower support tray 210 are adapted to raise and lower independently, driven by each of the pairs of actuator assemblies 125A and 125B. The support points 215 may be slightly offset from the support points 220 to facilitate actuator coupling and independent vertical lift of the respective support tray. Additionally, the offset of opposing support points 215, 220 relative the respective support tray 205, 210, provides enhanced stability during lifting and lowering.

The upper support tray 205 is sized slightly larger than the lower support tray 210, and may be placed in close proximity of the lower support tray 210 to minimize space in the interior volume of the load lock chamber 100. In one application, the support trays 205, 210 are adapted to nest into one another to reduce the interior volume of the load lock chamber 100. For example, the lower support tray 210 may be received by the upper support tray 205 in a nested configuration. Each of the upper support tray 205 and the lower support tray 210 includes a substantially planar upper surface for supporting a large area substrate, which in one embodiment is a plurality of substantially parallel support members 230, 235 disposed on the upper support tray 205 and lower support tray 210, respectively. In one application, the support members 230, 235 are structural members such as a rod or a bar having a solid or tubular cross section, a channel, an “I” beam or “H” beam, and combinations thereof. The support members 230, 235 are spaced apart to allow a robot blade or fingers 145A-145D (FIG. 1) to be received therebetween. Collectively, the support members 230, 235 provide a substantially planar surface to support a substrate while allowing access to the fingers 145A-145D or other supporting portion of a robot. In one embodiment, the support members 230, 235 include support pins 240 that are coupled to an upper surface of each support member 230, 240 and extend upwardly therefrom to define a substrate support surface. Each support pin 240 includes a friction reducing upper surface, such as polished surface or a rolling surface, for example a ball or pin.

Opposing ends of each support member 230, 235 are fixedly connected to respective base frames 233, 239 and include bent portions 231, 237 that facilitate support and spacing for each support member 230, 235. In one aspect, each of the support members 230, 235 on respective support trays 205, 210 are disposed in a first horizontal plane to define a supporting surface, and the respective base frames 233, 239 are disposed in a second horizontal plane, and the first and second planes are spaced-apart vertically. In one embodiment, the support members 230, 235 and base frames 233, 239 may be formed in a single body made of a same material, which include aluminum, carbon fiber, and combinations thereof. In alternate embodiments, the support members 230, 235 may be formed of discrete structural members made of aluminum or carbon fiber, and coupled to a respective base frame 233, 239 made of aluminum or carbon fiber. The support members 230, 235 and base frames 233, 239 may also be fabricated from other process resistant materials that are lightweight and minimize outgassing.

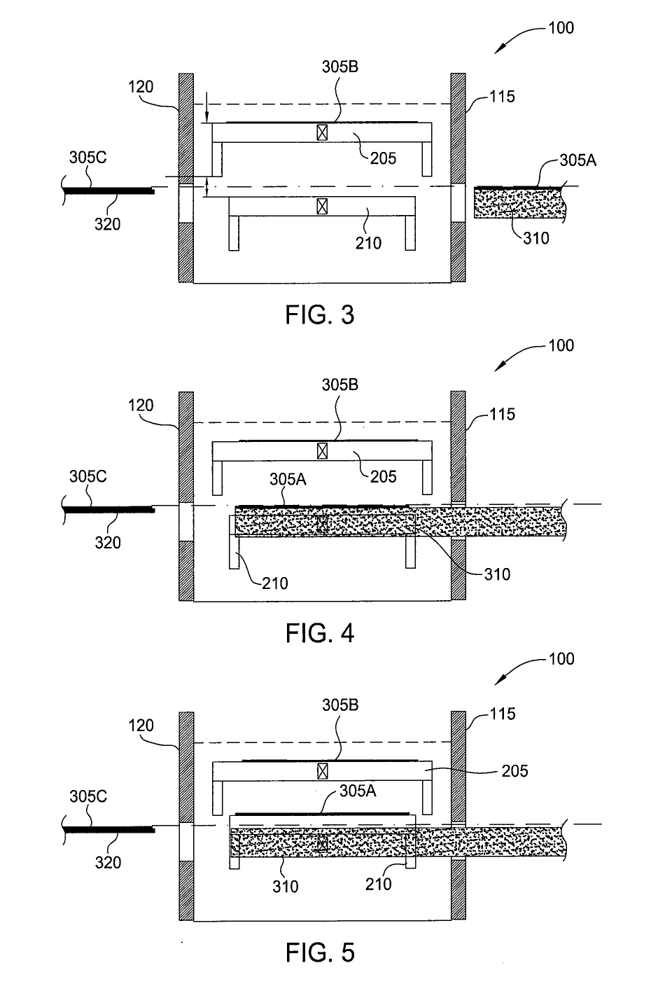

FIGS. 3-17 are schematic side views showing a plurality of transfer positions of substrates 305A-305C into and out of the load lock chamber 100 during a plurality of transfer cycles, according to embodiments described herein. The elements 310 and 320 represent conveyor portions of respective robot blades, end effectors, or a supporting portion of a transfer mechanism. In one embodiment, one or both of the conveyor portions 310, 320 may be an atmospheric transfer mechanism adapted to transfer substrates into or out of a clean room, a cassette, or other storage device. In another embodiment, one or both of the conveyor portions 310, 320 may be an on-tool transfer mechanism adapted to transfer substrates from one negatively pressurizable chamber to another, such as the conveyor 140 of FIG. 1. In either embodiment, the conveyor portions 310, 320 may comprise one or more blades or fingers, such as the fingers 145A-145D of FIG. 1, having a substantially planar upper surface for supporting and transferring a large area substrate. In this embodiment, each of the conveyor portions 310, 320 travel in a substantially horizontal plane to selectively enter and exit the load lock chamber 100 from the first end 115 and opposing second end 120 to facilitate transfer of substrates 305A-305C. More specifically, in each transfer cycle, either of the first conveyor 310 and second conveyor 320 enters the load lock chamber 100 to either: 1) load a substrate from the conveyor onto the upper or lower support tray, or 2) unload a substrate from the upper or lower support tray onto the conveyor.

In conjunction with FIGS. 3-6, a first transfer cycle for loading a substrate 305A from the first conveyor 310 to the lower support tray 210 is now detailed. The chamber 100 may at some point in the fabrication process, include a processed substrate that has been previously transferred to the chamber 100 from a vacuum chamber (not shown) coupled to first end 115, and is awaiting transfer to ambient atmosphere in the clean room. In this example an unprocessed substrate is supported by upper support tray 205 and is indicated as 305B.

In FIG. 3, an intermediate initial stage in the first transfer cycle is shown. The first conveyor 310 carrying the substrate 305A thereon has moved to a position proximate to the first end 115 of the chamber 100. To prepare the transfer of another substrate, the second conveyor 320 carrying a substrate 305C thereon may also move to a standby position proximate to the second end 120 of the chamber 100. In preparation for the transfer of the substrate 305A, the lower support tray 210 moves to an initial load position below the plane of the support surface of the first conveyor 310 on which the substrate 305A is placed. Furthermore, the upper support tray 205 has moved to an offset position above the lower support tray 210. The upper support tray 205 may also support the unprocessed substrate 305B that may be transferred out of the chamber 100 and into the vacuum chamber for processing.

Referring to FIG. 4, the first conveyor 310 carrying the substrate 305A then enters the chamber 100 through the first end 115, moves across the area of the lower support tray 210, and stops at a transfer position that is in substantial vertical alignment with the lower support tray 210. In this transfer position of the first conveyor 310, the substrate 305A carried thereon is located closely above the support surface of the lower support tray 210.

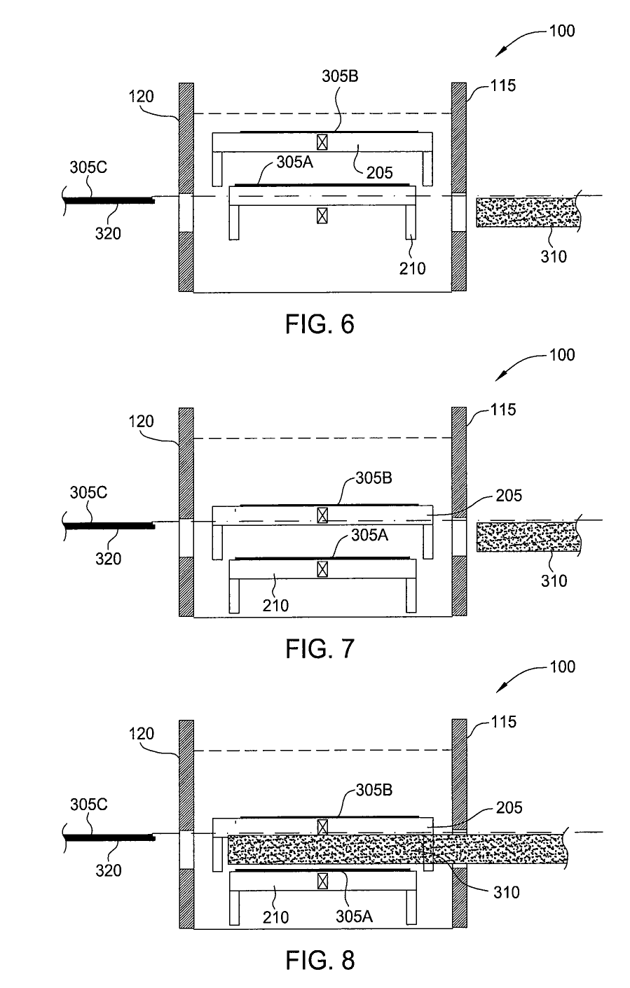

Referring to FIG. 5, while the first conveyor 310 remains stationary in its transfer position, the lower support tray 210 then moves upward relative to the upper support tray 205, which may be in a stationary state, so that the support surface of the lower support tray 210 passes above the support surface of the first conveyor 310 and consequently lifts the substrate 305A. The substrate 305A is thereby unloaded from the first conveyor 310 and is carried on the lower support tray 210. Once substrate 305A is supported by lower support tray 210, conveyor 310 may retract or exit the chamber 100 through first end 115, as shown in FIG. 6.

In conjunction with FIGS. 7-10, a second transfer cycle for unloading the substrate 305B from the upper support tray 205 to the first conveyor 310 is now described. In FIG. 7, an intermediate initial stage in the second transfer cycle is shown. In preparation for unloading the substrate 305B, the upper support tray 205 carrying the substrate 305B has moved to an initial unload position above the plane that contains the support surface of the first conveyor 310. Furthermore, the lower support tray 210 has moved to an offset position below the upper support tray 205. In one embodiment, the second transfer cycle may take place after the first transfer cycle described above has been completed.

Referring to FIG. 8, the first conveyor 310 then travels through the first end 115, moves across the area of the upper support tray 205, and stops at a transfer position that is in substantial alignment with the upper support tray 205. In this transfer position of the first conveyor 310, which may be the same as the transfer position shown in FIG. 4, the substrate 305A on the lower support tray 210 is located closely above the support surface of the first conveyor 310.

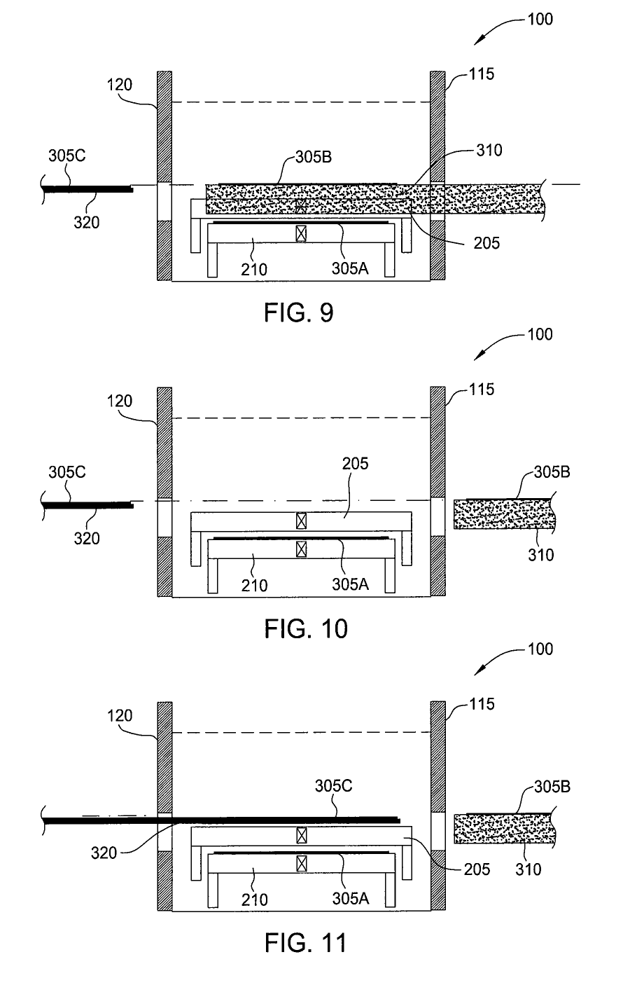

Referring to FIG. 9, while the first conveyor 310 remains stationary in its transfer position, the upper support tray 205 then moves downward from the initial unload position toward the lower support tray 210 so that the support surface of the upper support tray 205 passes below the support surface of the first conveyor 310. Consequently, the substrate 305B is unloaded from the upper support tray 205 and is carried on the first conveyor 310. As the upper support tray 205 descends to unload the substrate 305B, the lower support tray 210 lying in a resting position is at least partially received in a void formed by the construction of the upper support tray 205. This collapsible configuration of the upper and lower support trays 205 and 210 reduces the volume and space occupied by both upper and lower support trays 205 and 210 within the interior volume of the chamber 100, which facilitates a reduced height of the chamber 100. The reduced height, in turn, minimizes the internal volume needed to be pumped down and vented, which facilitates higher throughput.

Referring to FIG. 10, once the substrate 305B has been loaded thereon, the first conveyor 310 travels through the first end 115 to retrieve the substrate 305B out of the chamber 100. The substrate 305B may be an unprocessed substrate, as described above, and is transferred to the vacuum chamber where the substrate may be further processed, such as a testing procedure.

In conjunction with FIGS. 11-13, a third transfer cycle for loading a substrate 305C from the second conveyor 320 to the upper support tray 205 is now described. In FIG. 11, an intermediate initial stage in the third transfer cycle is shown. In preparation for loading the substrate 305C, the upper support tray 205 has moved to an initial load position below the plane that contains the support surface of the second conveyor 320. This initial load position of the upper support tray 205 may be similar to the configuration of the upper support tray 205 shown in FIG. 10, collapsed over the lower support tray 210. Furthermore, the second conveyor 320 has entered the chamber 100, and is placed at a transfer position in substantial alignment with the upper support tray 205. In this transfer position of the second conveyor 320, the substrate 305C carried thereon is located closely above the support surface of the upper support tray 205.

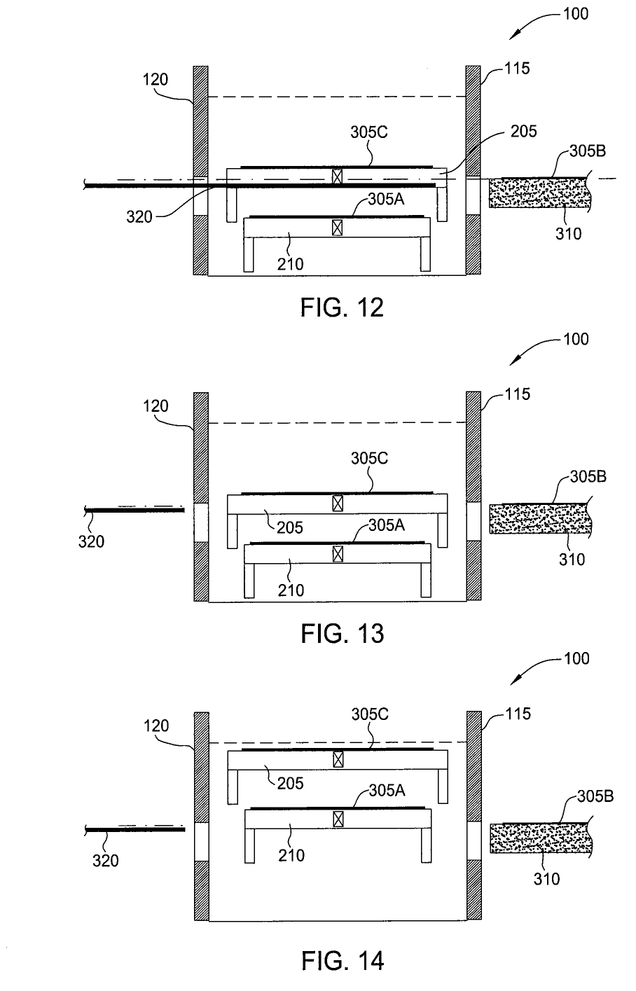

Referring to FIG. 12, while the second conveyor 320 remains stationary in its transfer position, the upper support tray 205 then moves upward so that the support surface of the upper support tray 205 passes above the support surface of the second conveyor 320 and consequently lifts the substrate 305C. The substrate 305C is thereby unloaded from the second conveyor 320 and is carried on the upper support tray 205.

Referring to FIG. 13, after the substrate 305C has been transferred from the second conveyor 320 onto the upper support tray 205, the second conveyor 320 exits the chamber 100 through the second end 120. Within the chamber 100, the upper support tray 205 and lower support tray 210 thus are respectively loaded with the substrates 305C and 305A.

In conjunction with FIGS. 14-17, a fourth transfer cycle for unloading the substrate 305A from the lower support tray 210 to the second conveyor 320 is now described. In FIG. 14, an intermediate initial stage in the fourth transfer cycle is shown. The lower support tray 210 carrying the substrate 305A has moved to an initial unload position above the plane that contains the support surface of the second conveyor 320 on which the substrate 305A is to be transferred. Furthermore, the upper support tray 205 has moved to an offset position above the lower support tray 210.

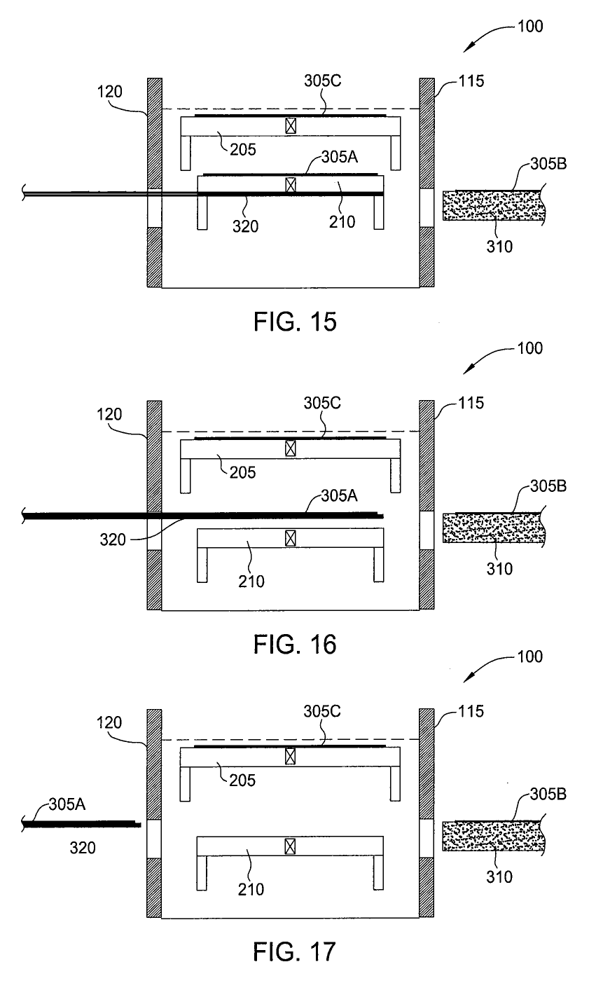

Referring to FIG. 15, the second conveyor 320 then travels through the second end 120, moves across the area of the lower support tray 210, and stops at a transfer position that is in substantial alignment with the lower support tray 210. In this transfer position of the second conveyor 320, the substrate 305A carried on the lower support tray 210 is located closely above the support surface of the second conveyor 320.

Referring to FIG. 16, while the second conveyor 320 remains stationary in its transfer position, the lower support tray 210 then moves downward so that the support surface of the lower support tray 210 passes below the support surface of the second conveyor 320. Consequently, the substrate 305A is unloaded from the lower support tray 210 and is carried on the support surface of the second conveyor 320.

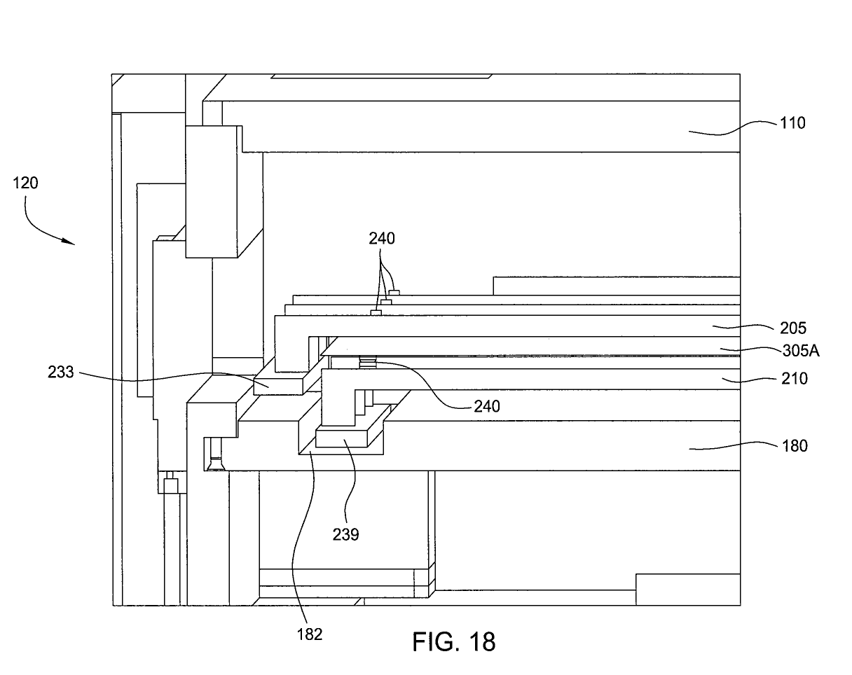

Referring to FIG. 17, after the substrate 305A has been transferred from the lower support tray 210 to the second conveyor 320, the second conveyor 320 then exits the chamber 100 through the second end 120 to transfer the substrate 305A out of the chamber 100.

As has been described above, the substrate support 200 thus is capable of supporting multiple substrates on at least the upper support tray 205 and lower support tray 210 that are adapted to raise and lower independently of each other. The upper support tray 205 and lower support tray 210 are thereby movable to a configuration where they fit into each other so as to occupy less volume.

FIG. 18 is an isometric cutaway view of a portion of the housing 110 of the chamber 100 of FIG. 1. The upper support tray 205 and lower support tray 210 are shown in a configuration where the trays 205, 210 are collapsed together, or fit into each other, at a lowered position similar to the view in FIG. 9. The upper support tray 205 and lower support tray 210 are sized to minimize the height of the interior volume of the housing 110, which minimizes vacuum pump-down time. For example, the upper support tray 205 is adapted to receive and at least partially envelop the lower support tray 210. In one embodiment, the lower support tray 210 is also adapted to be disposed in a recess 182 formed in a lower surface 180 of the housing 110, which further decreases the height requirement of the support trays 205, 210 and the interior volume.

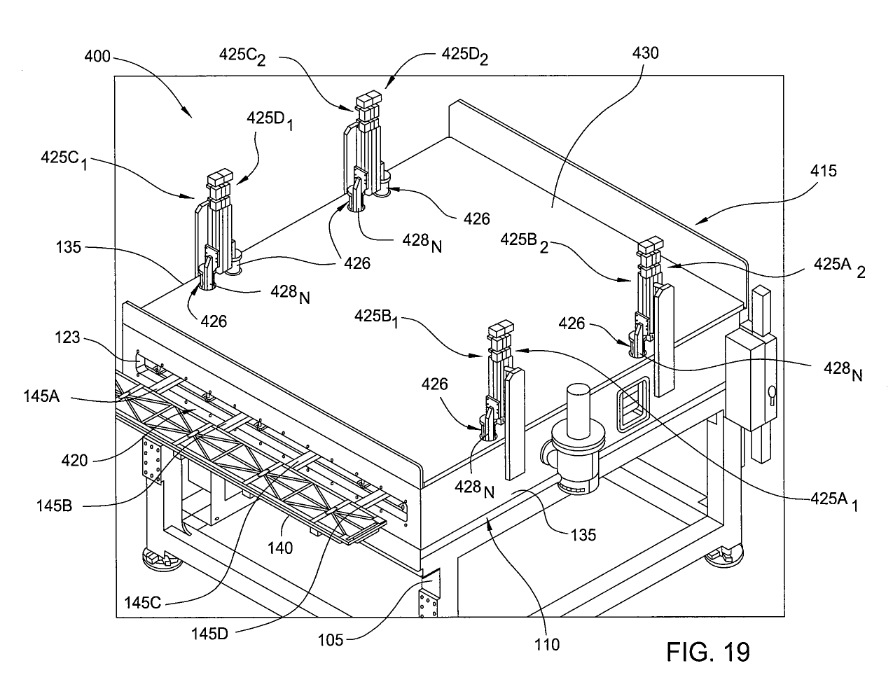

FIG. 19 is a schematic view illustrating another embodiment of a load lock chamber 400. Like the embodiment shown in FIG. 1, the load lock chamber 400 includes a sealable housing 110 that is disposed on a support frame 105 and upwardly covered by a lid 430. The housing 110 has a first end 115 and a second end 120, each of which includes an access port 123 that is opened and closed by a valve (not shown) for selective access by a conveyor 140 having spaced apart fingers 145A-145D adapted to support a large area substrate. However, instead of having actuators that are coupled to the substrate support structure through the sidewalls 135 of the housing 110, the load lock chamber 400 includes actuator assemblies 425A₁-425D₁, 425A₂-425D₂ that are coupled to the substrate support structure through respective openings formed in the lid 430. In the embodiment shown, the load lock chamber 400 includes four actuator assemblies 425A₁, 425B₁, 425A₂, and 425B₂ on one side of the load lock chamber 400, and four actuator assemblies 425C₁, 425C₂, 425D₁, and 425D₂ on an opposing side of the load lock chamber 400.

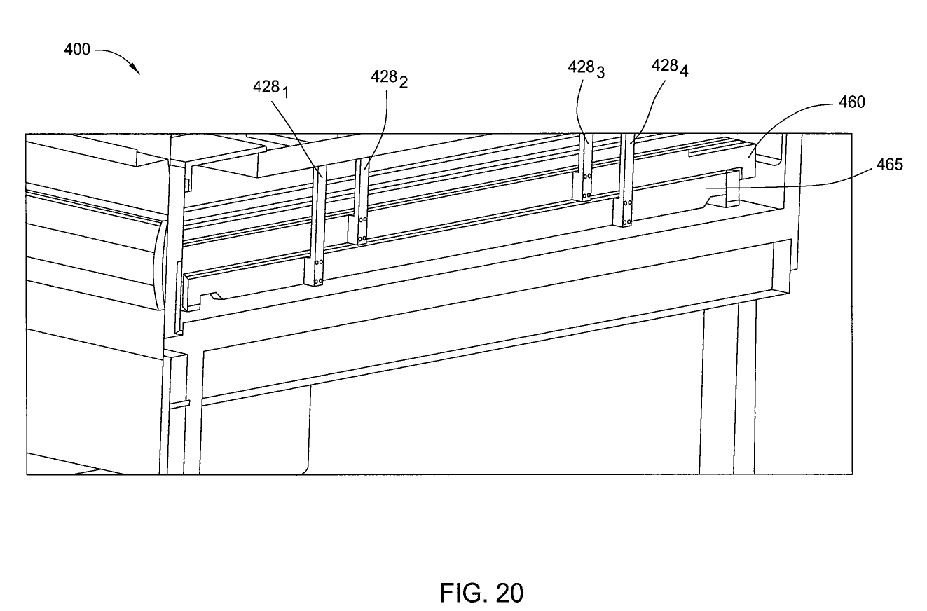

Each of the actuator assemblies 425A₁-425D₁, 425A₂-425D₂ include a motor or drive mechanism, which may be electrical, hydraulic, pneumatic, or other mechanical drive adapted to provide at least vertical movement to the respective support tray disposed in the interior volume. Referring to the actuator assemblies, the respective drive mechanism of each actuator assembly may be coupled to a support arm 428_{N} that is coupled to a support tray (FIG. 20). The actuator assemblies 425A₁-425D₁, 425A₂-425D₂ may be coupled to the lid 430 at an actuator/chamber interface 426, which comprises an opening in the lid 430 allowing access for respective support arms 428_{N}, and a sealing feature. In one embodiment, the sealing feature may be a flexible bellows, a flexible boot, or other type of seal adapted to provide vacuum sealing of the respective support arms 428_{N} and the chamber 400.

FIG. 20 shows an isometric view of a portion of the interior volume of the load lock chamber 400 shown in FIG. 19. The interior volume includes an upper support tray 460 and a lower support tray 465. Although only one side of the upper support tray 460 and lower support tray 465 is shown, actuator assemblies 425A₁, 425B₂, and 425D₁-425C₂ may be coupled to the upper support tray 460, and actuator assemblies 425B₁, 425A₂, and 425C₁, 425D₂ may be coupled to the lower support tray 465, in one embodiment. Other actuator assembly/support tray coupling schemes are also possible. The actuator assemblies are coupled to the support trays 460, 465 by respective support arms 4282, 4283 on the upper support tray 460 and support arms 428₁, 428₄ on the lower support tray 465. In one embodiment, the actuator assemblies 425B₁ and 425A₂ couple to outer support arms 428₁, 428₄ on the lower support tray 465, and actuator assemblies 425A₁ and 425B₂ couple to inner support arms 4282, 4283 on the upper support tray 460. Although not shown, the opposing sides of the support trays 460, 465 may be coupled similarly to actuator assemblies 425C(₁₋₂) and 425D(₁₋₂) While not shown, other embodiments of actuator assembly coupling schemes to the support trays 460, 465 are also contemplated in a manner that provides enhanced support and independent lifting of each support tray 460, 465.

While the invention has been described above in conjunction with certain particular embodiments, modifications and variations may be possible without departing from the scope of the invention. For example, instead of the illustrated embodiments using upward and downward movements of the upper/lower support tray relative to the stationary first/second conveyor to transfer a substrate, other embodiments may reversely configure the first/second conveyor to perform downward and upward motions while the upper/lower support tray remains in a stationary position, or alternatively a combination of motions of both the upper/lower support tray and the first/second conveyor toward each other.

Embodiments described herein are configured to minimize the interior volume of a transfer chamber 100 or 400. Testing of the chamber 100, having the support trays 205, 210 as described herein, has resulted in about a 40% reduction of the interior volume of the chamber 100. The minimized interior volume may reduce the number of vacuum pumps needed to pump-down the chamber 100 or 400 and/or shorten the cycle time of the system. The shortened cycle time may increase throughput and/or a reduction in the number of vacuum pumps may reduce the cost of the system.

While the foregoing is directed to embodiments of the present invention, other and further embodiments of the invention may be devised without departing from the basic scope thereof, and the scope thereof is determined by the claims that follow.

1. A vacuum chamber sized to receive at least two large area substrates, comprising:
a housing having an interior volume; and
a first support tray and a second support tray disposed in the interior volume, wherein each of the first and second support trays comprise:
a plurality of substantially parallel and spaced apart support members defining a first horizontal plane that are coupled to a base portion disposed in a second horizontal plane that is different than the first horizontal plane, wherein the first support tray has a greater dimension than the second support tray.

2. The vacuum chamber of claim 1, wherein each of the support members includes bent portions terminating at the base portion.

3. The vacuum chamber of claim 1, wherein each of the first and second support trays are coupled to two actuators.

4. The vacuum chamber of claim 1, wherein each of the first and second support trays are coupled to four actuators.

5. The vacuum chamber of claim 1, wherein one or more of the support members include support pins disposed on an upper surface thereof.

6. The vacuum chamber of claim 1, wherein the housing has a recess adapted to receive the base portion of at least one of the first and second support trays.

7. The vacuum chamber of claim 1, wherein either of the first and second support trays is made of one or more materials including aluminum, carbon fiber, and combinations thereof.

8. The vacuum chamber of claim 1, wherein the second support tray is adapted to fit into the first support tray.

9. The vacuum chamber of claim 1, wherein the vacuum chamber is a load lock chamber.

10. A substrate transfer system, comprising:
a chamber housing having at least one access port, wherein the chamber housing includes a first substrate support tray and a second substrate support tray parallel to the first substrate support tray, wherein the first and second substrate support trays are independently movable along a vertical axis; and
a substrate conveyor movable into and out of the chamber housing to transfer a substrate between the substrate conveyor and either of the first and second substrate support tray, wherein the first substrate support tray and the second substrate support tray are movable relative to each other to a position where a portion of the second substrate support tray is nested in the first substrate support tray to reduce an internal volume of the housing.

11. The system of claim 10, wherein the first substrate support tray is larger than the second substrate support tray in size.

12. The system of claim 10, wherein at least the first substrate support tray includes a plurality of laterally spaced apart support members that are configured to receive a portion of the substrate conveyor therebetween.

13. The system of claim 12, wherein each of the support members includes two opposite end portions that bend to connect to a base frame at an angle orthogonal to the support members.

14. The system of claim 12, wherein the support members include a plurality of support pins projecting upward for supporting the substrate.

15. The system of claim 10, wherein the substrate conveyor is movable to a transfer position inside the housing that is in substantial alignment with either of the first and second substrate support tray.

16. The system of claim 15, wherein the first substrate support tray is configured to move through the substrate conveyor kept stationary in the transfer position to transfer a substrate.

17. The system of claim 16, wherein the first substrate support tray is operable to move upward through the substrate conveyor to lift a substrate carried thereon.

18. The system of claim 16, wherein the first substrate support tray carrying a substrate is configured to move downward through the substrate conveyor to unload the substrate on the substrate conveyor.

19. A method of transferring a large area substrate, comprising:
placing the substrate on a substrate conveyor;
moving the substrate conveyor into a load lock chamber having a substrate support structure, wherein the substrate support structure includes at least a first substrate support tray and a second substrate support tray independently movable along a vertical axis; and
operating the substrate support structure to transfer the substrate from the substrate conveyor to either of the first and second substrate support trays, wherein operating the substrate support structure includes moving the first substrate support tray relative to the second substrate support tray to a position where a portion of the second substrate support tray is nested in the first substrate support tray to reduce an interior volume of the load lock chamber.

20. The method of claim 19, wherein the first substrate support tray is larger than the second substrate support tray in size.

21. The method of claim 19, wherein at least the first substrate support tray includes a plurality of spaced apart support members adapted to receive a portion of the substrate conveyor therebetween.

22. The method of claim 21, wherein each of the support members include two opposite end portions that bend downward to connect to a base frame.

23. The method of claim 22, wherein moving the first substrate support tray relative to the second substrate support tray includes placing the first and second substrate support trays in a position where the end portions of the support members at least partially envelop a portion of the second substrate support tray.

24. The method of claim 19, wherein moving the substrate conveyor into the load lock chamber includes moving the substrate conveyor to a transfer position in substantial alignment with either of the first and second substrate support tray.

25. The method of claim 24, wherein operating the substrate support structure further comprises independently moving the first substrate support tray upward through the substrate conveyor to load the substrate on the first substrate support tray.
